(19) United States
(12) Patent Application Publication
(10) Pub. No.: US 2022/0319909 A1
(43) Pub. Date: Oct. 6, 2022

(54) METHOD FOR MANUFACTURING A SEMICONDUCTOR MEMORY DEVICE

(71) Applicant: NANYA TECHNOLOGY CORPORATION, New Taipei City (TW)

(72) Inventors: CHING-LIANG KAO, TAICHUNG CITY (TW); WEN-CHIEH WU, TAOYUAN CITY (TW); LI-LING KE, NEW TAIPEI CITY (TW)

(21) Appl. No.: 17/220,072

(22) Filed: Apr. 1, 2021

(51) Int. Cl. H01L 21/762; H01L 21/02; H01L 21/265

(52) U.S. Cl. CPC H01L 21/76237; H01L 21/0217; H01L 21/0228; H01L 21/26513; H01L 21/26586

(57) ABSTRACT

The present disclosure provides a method for manufacturing a semiconductor memory device. Because the present method includes applying a dopant-implanted layer on a semiconductor memory substrate before growing a silicon nitride layer on the substrate, the silicon nitride layer can be grown at an increased rate. The present disclosure avoids a problem encountered in the prior art wherein a seam having a greater length contacts an edge of a contact plug of a semiconductor memory device. Hence, a leakage problem at subsequent operations of semiconductor manufacture can be avoided, and the product yield can be significantly improved.

### TECHNICAL FIELD

The present disclosure generally relates to the field of semiconductor memory devices, and more particularly, to a method for manufacturing a semiconductor memory device which exhibits an increased growth rate of a silicon nitride layer and simultaneously reduces a seam length during a silicon nitride deposition.

### DISCUSSION OF THE BACKGROUND

For many semiconductor device manufacturing processes, there is a need to fill narrow trenches having high aspect ratios, for example greater than 10:1, with no voiding. One example of such a process is shallow trench isolation (STI), in which the film needs to be of high quality and have very low leakage throughout the trench. As the dimensions of semiconductor device structures continue to decrease and the aspect ratios increase, post-curing processes become increasingly difficult and result in films with varying composition throughout the filled trench.

Conventionally, amorphous silicon (a-Si) has been used in semiconductor manufacturing processes, since a-Si generally provides good etch selectivity with respect to other films, such as silicon oxide (SiO) and amorphous carbon (a-C). However, conventional a-Si deposition methods, such as plasma-enhanced chemical vapor deposition (PECVD) and conformal deposition, cannot be used to gapfill high aspect ratio trenches due to a tendency for seams to form in the high aspect ratio trenches. A seam includes gaps that form in the trench between the sidewalls, and that open further during post-curing processes and ultimately cause decreased throughput or even semiconductor device failure. Moreover, PECVD of a-Si generally results in voiding at the bottom of the trench, which may also result in decreased device performance or even failure.

As is known in the art, group III nitrides are used in many semiconductor devices. It is known that silicon nitride deposition may be performed at a high temperature (e.g., about 630° C.) to obtain a silicon nitride layer having good quality, but a long seam having a large width may be formed during the silicon nitride deposition. Further, performing silicon nitride deposition at a low temperature (e.g., about 550° C.) may reduce length of seams that are formed, but the resulting silicon nitride layer will be low in quality. A two-step temperature-controlled process for silicon nitride deposition has been proposed as a compromise, and comprises first depositing silicon nitride at a low temperature (e.g., about 550° C.), so as to reduce the length of resulting seams, and then depositing additional silicon nitride at an elevated temperature (e.g., about 630° C.) so as to obtain a silicon nitride layer of high quality. However, the two-step temperature-controlled process needs to be carefully controlled, and adds difficulty and cost to the manufacture of semiconductor devices. FIG. 1 shows an illustrative cross-sectional view of a semiconductor memory device 10 obtained using the two-step temperature-controlled process of the prior art. As shown in FIG. 1, the device 10 has a substrate 101, which includes a trench 103. During formation of a silicon nitride layer 107, a seam 105 can form, wherein the seam 105 can have significant length and can contact an edge of a contact plug 109.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a method for manufacturing a semiconductor memory device. The method comprises the steps of: providing a semiconductor memory substrate including a plurality of trenches; conformally forming a first silicon nitride layer on the plurality of trenches; performing ion implantation using atomic layer deposition (ALD) to implant a dopant at a tilting angle (θ) of between about 5 degrees and about 30 degrees to form a dopant-implanted layer on the first silicon nitride layer; and growing a second silicon nitride layer on the dopant-implanted layer.

In some embodiments, the semiconductor memory substrate is selected from the group consisting of a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a group III-V compound semiconductor, and combinations thereof.

In some embodiments, the trench has an aspect ratio of between 10:1 and 60:1.

In some embodiments, the step of conformally forming a first silicon nitride layer on the plurality of trenches is carried out using atomic layer deposition (ALD), atomic layer epitaxy (ALE), atomic layer chemical vapor deposition (ALCVD), spin-coating, sputtering, chemical vapor deposition (CVD), or physical vapor deposition (PVD).

In some embodiments, the step of performing ion implantation is carried out using ALD to implant a dopant at a tilting angle (θ) of between about 5 degrees and about 20 degrees.

In some embodiments, the step of performing ion implantation is carried out using ALD to implant a dopant at a tilting angle (θ) of about 7 degrees.

In some embodiments, the step of performing ion implantation is carried out using ALD to implant a dopant at a tilting angle (θ) of about 17 degrees.

In some embodiments, the step of performing ion implantation is carried out using a dopant selected from the group consisting of fluorine, carbon, boron, arsenic, phosphorus, nitrogen, argon, germanium, and indium.

In some embodiments, the step of performing ion implantation is carried out with an ion dose in a range of about 3.0×10¹³ to about 5.0×10¹⁵ ions/cm².

In some embodiments, the step of performing ion implantation is carried out with an energy in a range of about 100 eV to about 100 KeV.

Another aspect of the present disclosure provides a method for manufacturing a semiconductor memory device. The method comprises steps of: providing a semiconductor memory substrate including a plurality of trenches, wherein each trench has a bottom and a pair of sidewalls; conformally depositing a first silicon nitride layer on the plurality of trenches; performing ion implantation to form a dopant-implanted layer on the first silicon nitride layer, wherein the bottom of the trench receives a first ion dose and the pair of sidewalls of the trench receives a second ion dose, and the first ion dose is 10 to 100 times the second ion dose; and growing a second silicon nitride layer on the dopant-implanted layer.

In some embodiments, the semiconductor memory substrate is selected from the group consisting of a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a group III-V compound semiconductor, and combinations thereof.

In some embodiments, the trenches have an aspect ratio of between 10:1 and 60:1.

In some embodiments, the step of conformally forming a first silicon nitride layer on the plurality of trenches is carried out using spin-coating, sputtering, chemical vapor deposition (CVD), or physical vapor deposition (PVD).

In some embodiments, the step of performing ion implantation is carried out using a dopant selected from the group consisting of fluorine, carbon, boron, arsenic, phosphorus, nitrogen, argon, germanium, and indium.

In some embodiments, the first ion dose is in a range of about 3.0×10¹⁴ ions/cm² to about 5.0×10¹⁵ ions/cm².

In some embodiments, the first ion dose is 50 times the second ion dose.

In some embodiments, the first ion dose is 70 times the second ion dose.

In some embodiments, the step of performing ion implantation is carried out with an energy in a range of about 100 eV to about 100 KeV.

In some embodiments, the step of performing ion implantation is carried out with an energy in a range of about 1 KeV to about 100 KeV.

Due to the design of the above-described method for manufacturing a semiconductor memory device, the second silicon nitride layer can be grown at an increased rate. A silicon nitride layer (i.e., the second silicon nitride layer) of high quality with a seam having a short length can be obtained. The method of the present disclosure avoids a problem encountered in the prior art wherein a seam having a greater length contacts an edge of a contact plug of a semiconductor memory device. Hence, a leakage problem in subsequent operations of semiconductor manufacture can be avoided and product yield can be significantly improved.

The foregoing has outlined rather broadly the features and technical advantages of the present disclosure in order that the detailed description of the disclosure that follows may be better understood. Additional features and technical advantages of the disclosure are described hereinafter, and form the subject of the claims of the disclosure. It should be appreciated by those skilled in the art that the concepts and specific embodiments disclosed may be utilized as a basis for modifying or designing other structures, or processes, for carrying out the purposes of the present disclosure. It should also be realized by those skilled in the art that such equivalent constructions do not depart from the spirit or scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is an illustrative cross-sectional view of a semiconductor memory device obtained using a two-step temperature-controlled process of the prior art.

FIG. 2 is a representative flow diagram of a method for manufacturing a semiconductor memory device according to an embodiment of the present disclosure.

FIG. 3A is a cross-sectional view of the semiconductor memory device after the performing of step S201 in FIG. 2.

FIG. 3B is a cross-sectional view of the semiconductor memory device after the performing of step S203 in FIG. 2.

FIG. 3C is a cross-sectional view of the semiconductor memory device after the performing of step S205 in FIG. 2.

FIG. 3D is a cross-sectional view of the semiconductor memory device after the performing of step S207 in FIG. 2.

FIG. 4 is a representative flow diagram of a method for manufacturing a semiconductor memory device according to another embodiment of the present disclosure.

FIG. 5A is a cross-sectional view of the semiconductor memory device after the performing of step S401 in FIG. 4.

FIG. 5B is a cross-sectional view of the semiconductor memory device after the performing of step S403 in FIG. 4.

FIG. 5C is a cross-sectional view of the semiconductor memory device after the performing of step S405 in FIG. 4.

FIG. 5D is a cross-sectional view of the semiconductor memory device after the performing of step S407 in FIG. 4.

FIGS. 6A to 6I are SEM images of an ALD silicon nitride deposition map of the following dopants after the performing of step S205 in FIG. 2: fluorine (FIG. 6A), carbon (FIG. 6B), boron (FIG. 6C), arsenic (FIG. 6D), phosphorus (FIG. 6E), nitrogen (FIG. 6F), argon (FIG. 6G), germanium (FIG. 6H), and indium (FIG. 6I).

FIG. 6J is an SEM image of an ALD silicon nitride deposition map of a comparison wafer that has not undergone step S203 in FIG. 2.

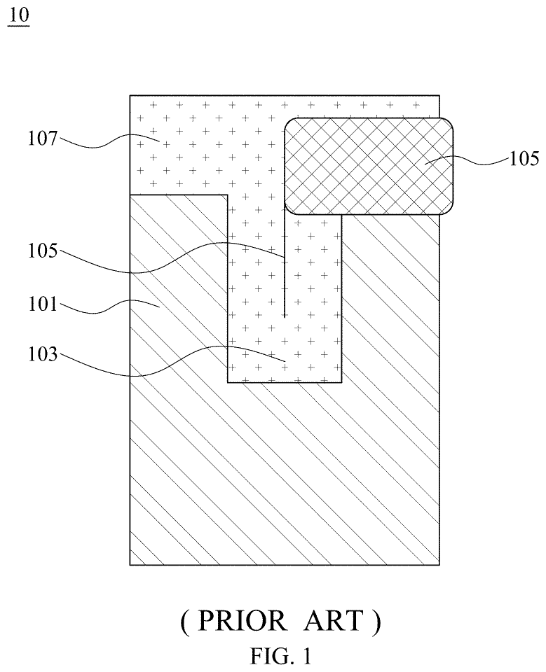

### DETAILED DESCRIPTION

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Embodiments (or examples) of the disclosure illustrated in the drawings are now described using specific language. It shall be understood that no limitation to the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless specifically stated or obvious from the context, as used herein, the term “about” is understood to include a range of normal tolerance in the art, for example, within 2 standard deviations of the mean. “About” can be understood as within 10%, 9%, 8%, 7%, 6%, 5%, 4%, 3%, 2%, 1%, 0.5%, 0.1%, 0.05%, or 0.01% of the standard value. Unless otherwise clear from the context, all numerical values provided herein are modified by the term about.

It shall be understood that, although the terms first, second, third, etc. may be used herein to describe various elements, components, regions, layers or sections, these elements, components, regions, layers or sections are not limited by these terms. Rather, these terms are merely used to distinguish one element, component, region, layer or section from another element, component, region, layer or section. Thus, a first element, component, region, layer or section discussed below could be termed a second element, component, region, layer or section without departing from the teachings of the present inventive concept.

The present disclosure will be described in detail with reference to the accompanying drawings with numbered elements. It should be noted that the drawings are in greatly simplified form and are not drawn to scale. Moreover, dimensions have been exaggerated in order to provide a clear illustration and understanding of the present invention.

The method for manufacturing a semiconductor memory device of the present disclosure will be explained in detail below along with drawings.

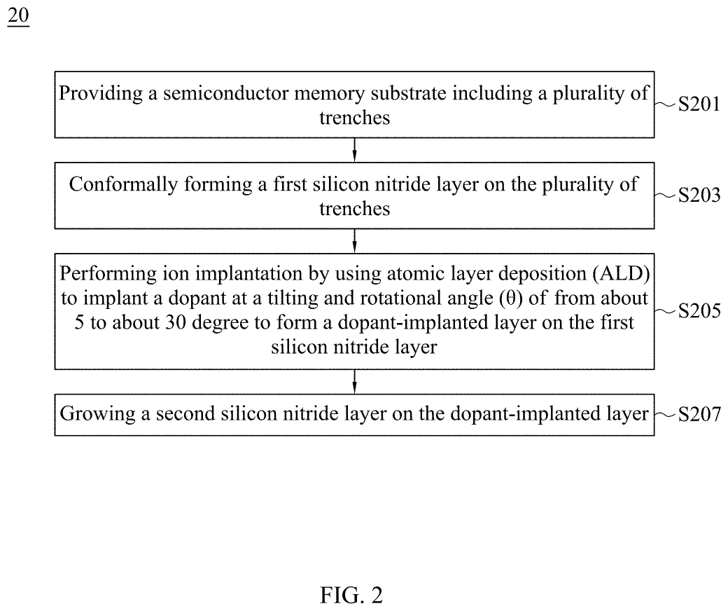

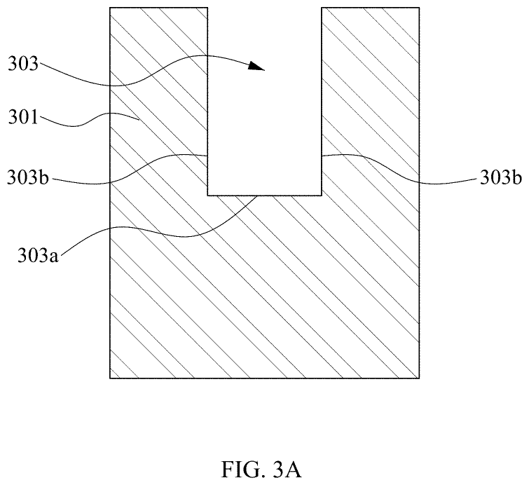

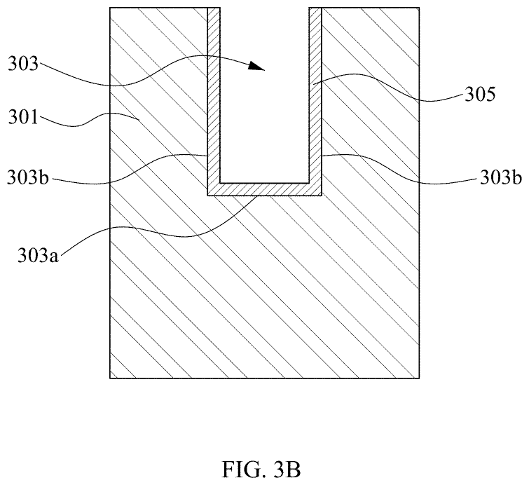

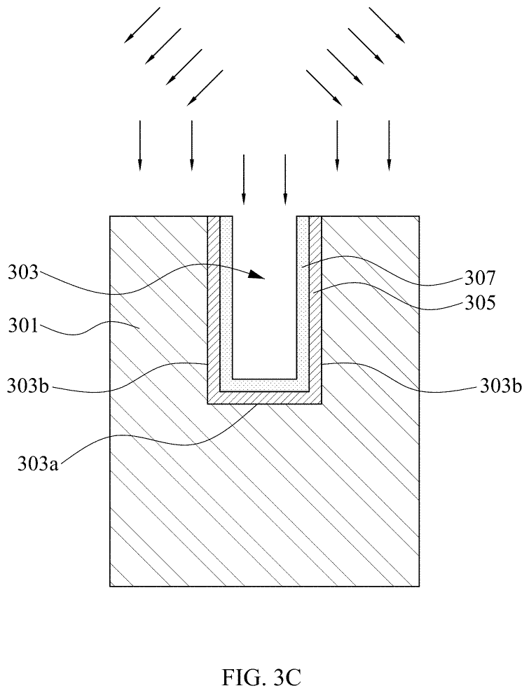

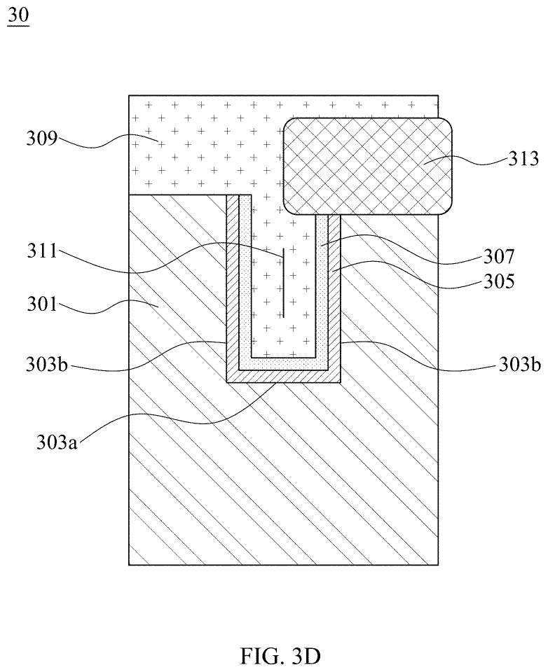

FIG. 2 is a representative flow diagram of a method 20 for manufacturing a semiconductor memory device 30 according to an embodiment of the present disclosure. FIGS. 3A, 3B, 3C, and 3D are cross-sectional views of the semiconductor memory device 30 after the performing of steps S201, S203, S205, and S207 in FIG. 2.

Referring to FIG. 2 and FIG. 3A, in step S201, a semiconductor memory substrate 301 including a plurality of trenches 303 is provided. Each trench 303 has a bottom 303a and a pair of sidewalls 303b. In the present disclosure, the term “substrate” means and includes a base material or construction upon which materials are formed. It will be appreciated that the substrate may include a single material, a plurality of layers of different materials, a layer or layers having regions of different materials or different structures in them, or another similar arrangement. In some embodiments, the semiconductor memory substrate 301 may be a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a group III-V compound semiconductor, a combination thereof, or the like.

In step S201, an etch process, such as an anisotropic dry etch process or a post reactive ion etching (RIE) process, may be performed to form a plurality of trenches 303 in the semiconductor memory substrate 301. The etch process may be continuously performed until a desired depth of the trenches 303 is achieved. Preferably, the trenches 303 have an aspect ratio of between 10:1 and 60:1, more preferably between 20:1 and 60:1, and even more preferably between 30:1 and 60:1. Optionally, a cleaning process using a reducing agent may be optionally performed to remove defects on the bottom 303a and sidewalls 303b of the trenches 303 of the semiconductor memory substrate 301. The reducing agent may be titanium tetrachloride, tantalum tetrachloride, or a combination thereof.

Referring to FIG. 2 and FIG. 3B, in step S203, a first silicon nitride layer 305 may be conformally formed on and attached to the bottom 303a and the sidewalls 303b of the trench 303. A process such as atomic layer deposition (ALD), atomic layer epitaxy (ALE), atomic layer chemical vapor deposition (ALCVD), spin-coating, sputtering, chemical vapor deposition (CVD), physical vapor deposition (PVD), or the like can be used to apply a first silicon nitride layer 305 on the plurality of trenches 303 of the semiconductor memory substrate 301. In a preferred embodiment of the present disclosure, the step of conformally forming a first silicon nitride layer 305 on the plurality of trenches 303 is carried out using ALD.

Referring to FIG. 2 and FIG. 3C, in step S205, ion implantation can be performed using electrostatic scanning, electromagnetic scanning, mechanical scanning, or a combination thereof. In electrostatic or electromagnetic scanning, the wafer is held stationary and the beam is moved along x- and y-axes. This is typically used in a single wafer process. Ion implantation is an adding process in which dopant atoms are forcefully added into a semiconductor substrate by means of energetic, ion beam injection. Ion implantation is the dominant doping method in the semiconductor industry and is commonly used for various doping processes in IC fabrication. According to an embodiment of the present disclosure, ion implantation is carried out using atomic layer deposition (ALD) to implant a dopant at a tilting angle (θ) between about 5 degrees and about 30 degrees, preferably between about 5 degrees and about 20 degrees, and more preferably about 7 degrees or about 17 degrees, to form a dopant-implanted layer 307 on the first silicon nitride layer 305.

According to an embodiment of the present disclosure, the step of performing ion implantation is carried out using a dopant selected from the group consisting of fluorine, carbon, boron, arsenic, phosphorus, nitrogen, argon, germanium, and indium. Preferably, the dopant is argon or germanium.

According to an embodiment of the present disclosure, the step of performing ion implantation is carried out with an energy in a range of about 1 KeV to about 50 KeV and an ion dose in a range of about 5.0×10¹⁴ to about 5.0×10¹⁵ ions/cm². Preferably, the step of performing ion implantation is carried out using argon (Ar) as a dopant with an ion dose in a range from about 2.0×10¹⁵ to about 3.0×10¹⁵ ions/cm² and an energy in a range from about 2 KeV to about 20 KeV, or carried out using germanium (Ge) as a dopant with an ion dose in a range from about 3.0×10¹⁴ to about 1.0×10¹⁵ ions/cm² and an energy in a range from about 10 KeV to about 20 KeV.

Referring to FIG. 2 and FIG. 3D, in step S207, a process such as atomic layer deposition (ALD), atomic layer epitaxy (ALE), atomic layer chemical vapor deposition (ALCVD), spin-coating, sputtering, chemical vapor deposition (CVD), physical vapor deposition (PVD), or the like can be used to grow a second silicon nitride layer 309 on the dopant-implanted layer 307. Preferably, the step of growing the second silicon nitride layer 309 on the dopant-implanted layer 307 is carried out using ALD. As shown in FIG. 3D, a seam 311 having a short length is achieved in accordance with the method of the present disclosure. The seam 311 is separated from an edge of a contact plug 313, thus avoiding a problem encountered in the prior art wherein a seam having a greater length contacts an edge of a contact plug of a semiconductor memory device.

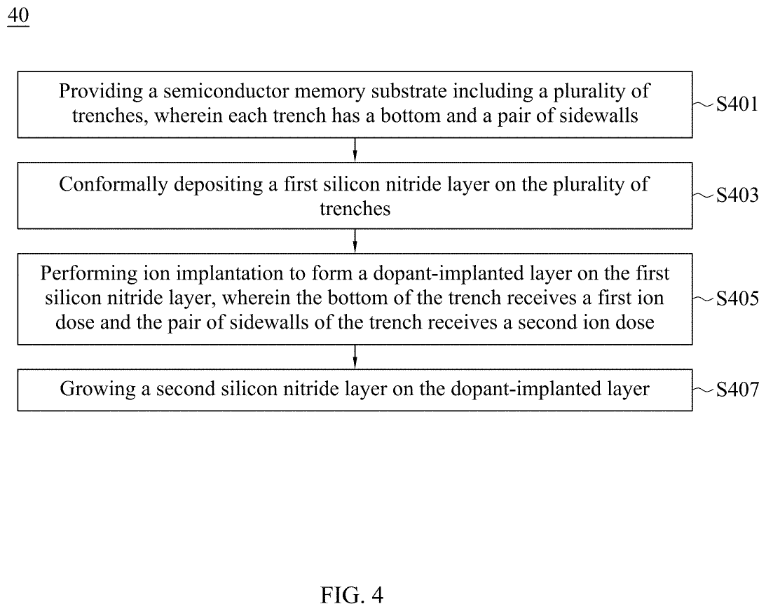

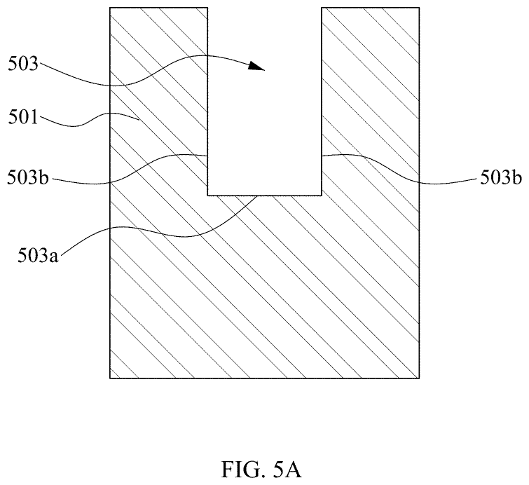

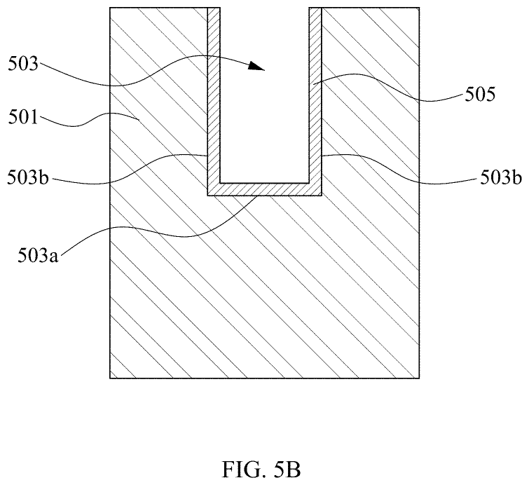

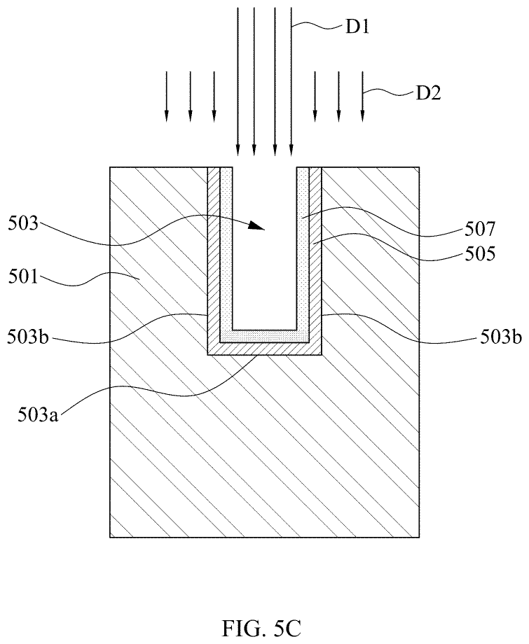

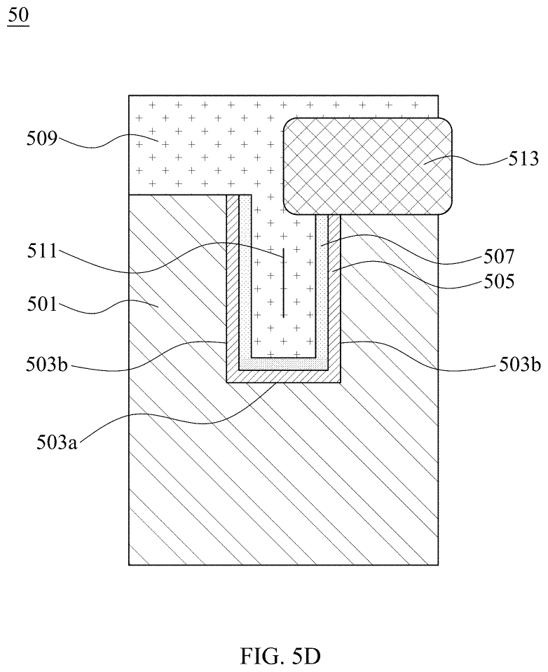

FIG. 4 is a representative flow diagram of a method 40 for manufacturing a semiconductor memory device according to another embodiment of the present disclosure. FIGS. 5A, 5B, 5C, and 5D are cross-sectional views of the semiconductor memory device after the performing of step S401, step S403, step S405, and step S407 in FIG. 4.

Referring to FIG. 4 and FIG. 5A, in step S401, a semiconductor memory substrate 501 including a plurality of trenches 503 is provided. Each trench 503 has a bottom 503a and a pair of sidewalls 503b. The formation of the plurality of trenches 503 may be performed according to the procedures described for step S203.

Referring to FIG. 4 and FIG. 5B, in step S403, a first silicon nitride layer 505 may be conformally formed on and attached to the bottom 503a and the sidewalls 503b of the trench 503. The formation of the first silicon nitride layer 505 may be performed according to the procedures described for step S205.

Referring to FIG. 4 and FIG. 5C, in step S405, ion implantation is performed using different ion doses for the bottom and the sidewalls of the trench 503. According to an embodiment of the present disclosure, the bottom 503a of the trench 503 receives a first ion dose D1 and the pair of sidewalls 503b of the trench 503 receive a second ion dose D2, wherein the first ion dose D1 is 10 to 100 times the second ion dose D2. Preferably, the first ion dose D1 is in a range of about 3.0×10¹⁴ ions/cm² to about 5.0×10¹⁵ ions/cm², and the first ion dose D1 is 50 times the second ion dose D2. More preferably, the first ion dose D1 is in a range of about 3.0×10¹⁴ ions/cm² to about 5.0×10¹⁵ ions/cm², and the first ion dose D1 is 70 times the second ion dose D2. According to an embodiment of the present disclosure, the step of performing ion implantation is carried out with an energy in a range of about 100 eV to about 100 KeV. Preferably, the step of performing ion implantation is carried out with an energy in a range of about 1 KeV to about 100 KeV.

Referring to FIG. 4 and FIG. 5D, in step S407, a second silicon nitride layer 509 is grown on a dopant-implanted layer 507. The formation of the second silicon nitride layer 509 may be performed according to the procedures described for step S207. As shown in FIG. 5D, a seam 511 having a short length is achieved in accordance with the method of the present disclosure. The seam 511 is separated from an edge of a contact plug 513, thus avoiding a problem encountered in the prior art wherein a seam having a greater length contacts an edge of a contact plug of a semiconductor memory device.

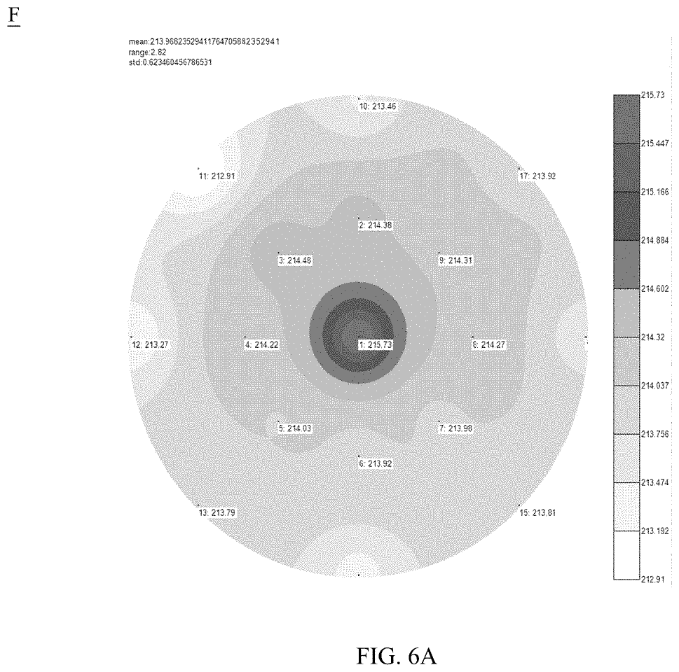

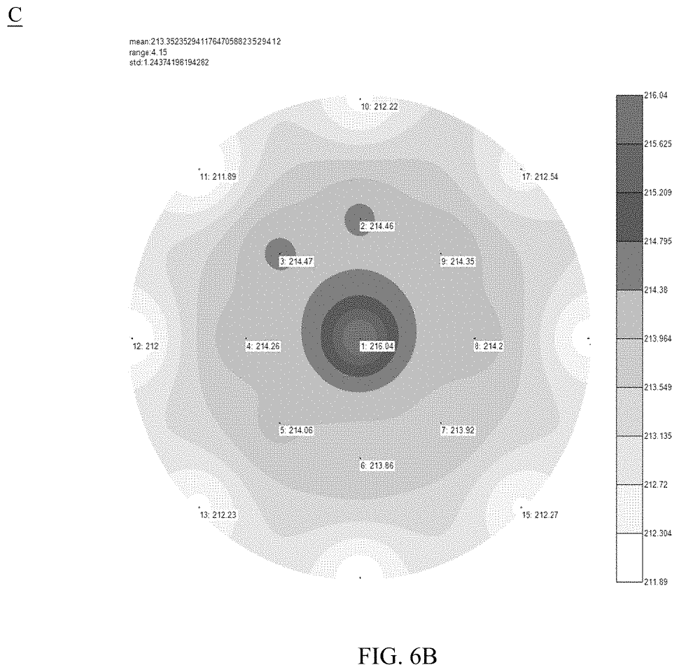

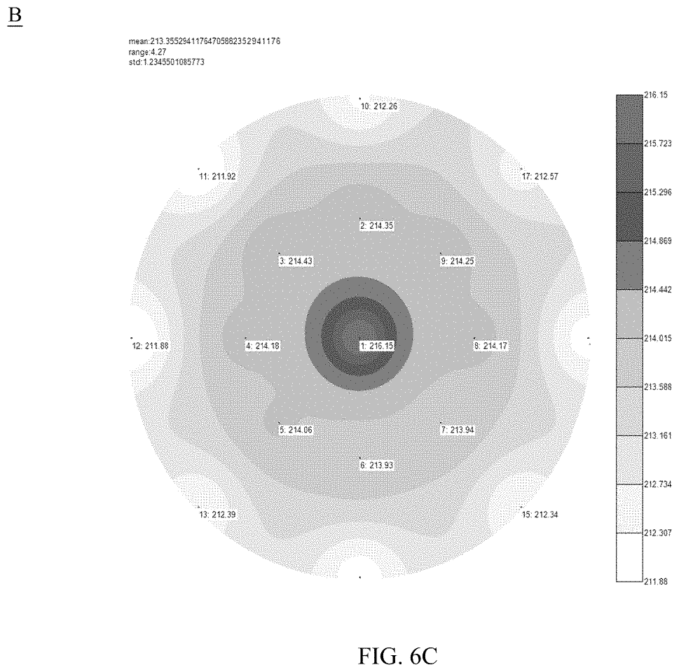

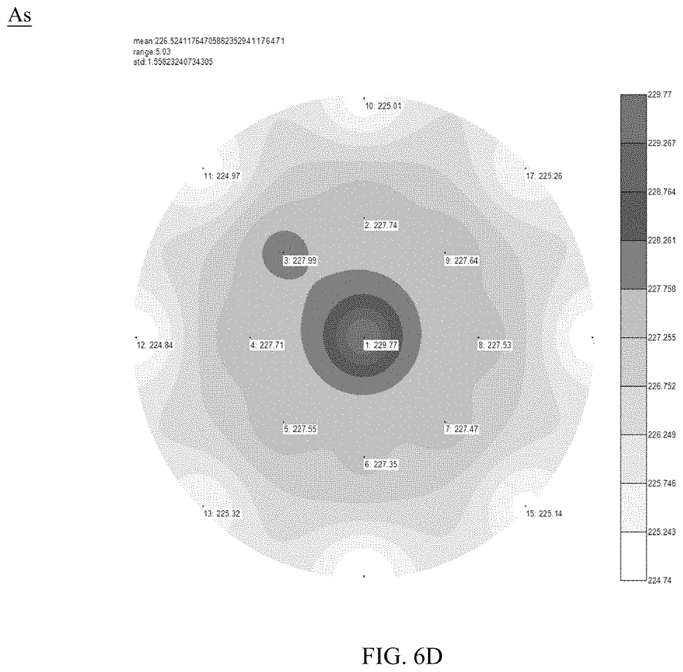

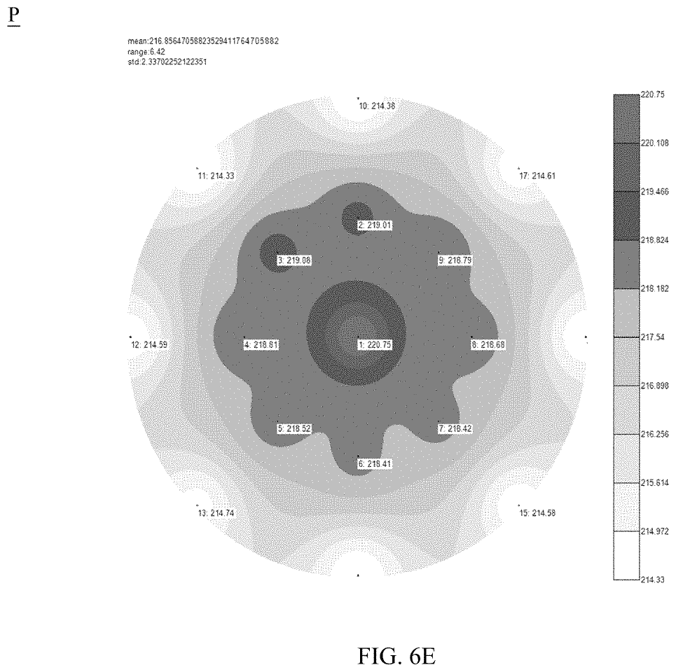

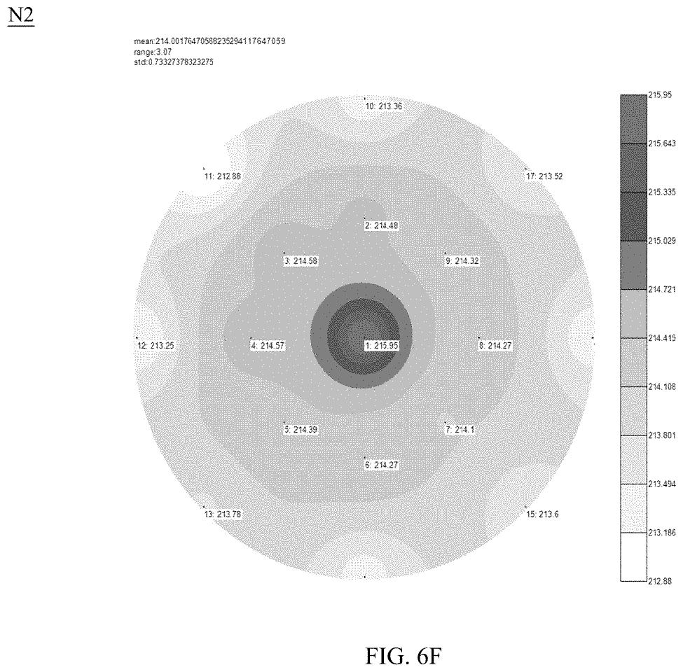

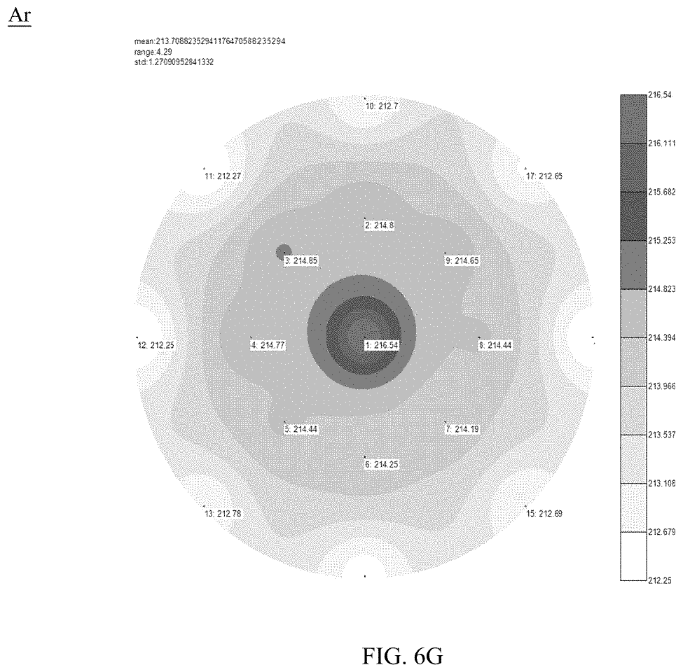

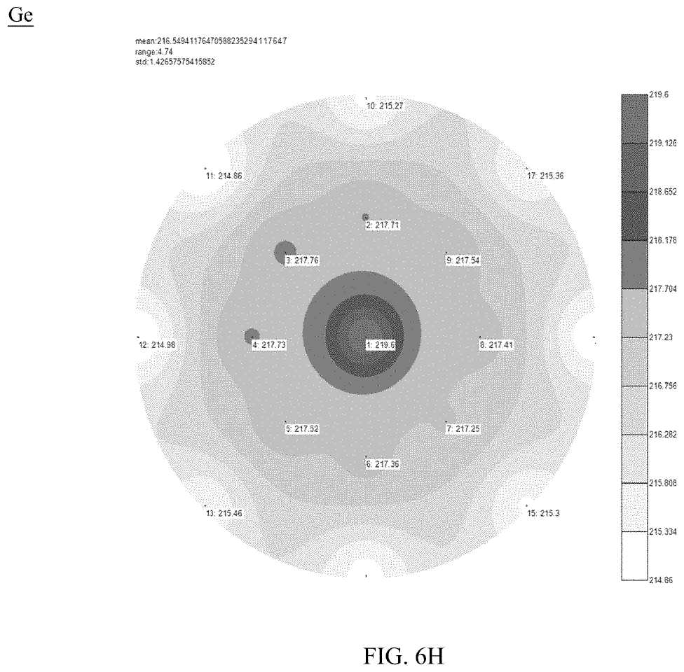

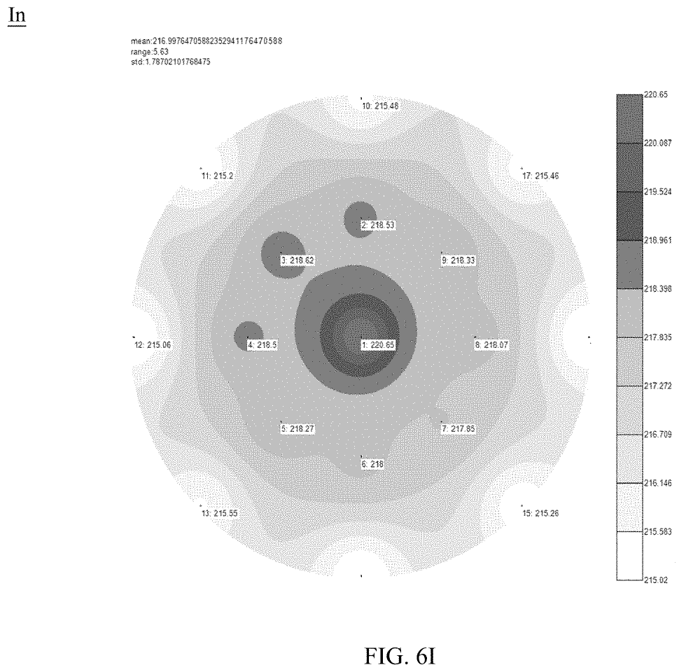

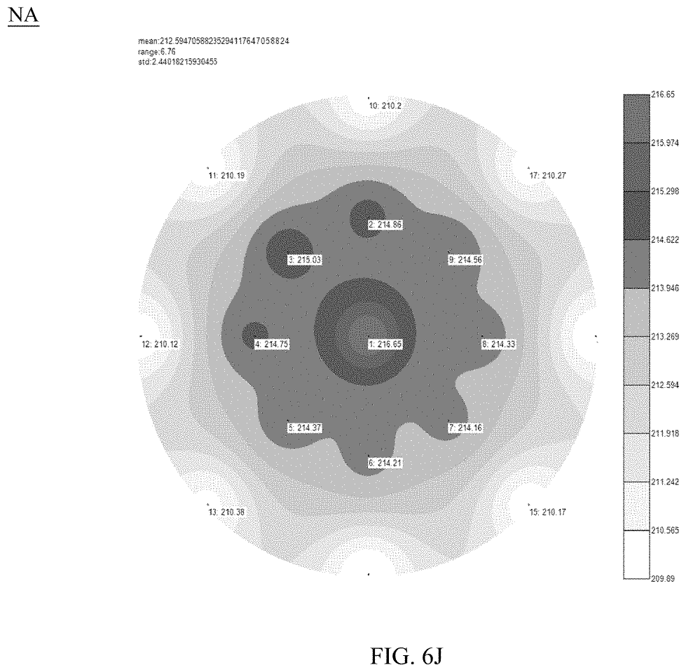

FIGS. 6A to 6I are SEM images of the ALD silicon nitride deposition map of the following dopants after the performing of step S205 in FIG. 2: fluorine (FIG. 6A), carbon (FIG. 6B), boron (FIG. 6C), arsenic (FIG. 6D), phosphorus (FIG. 6E), nitrogen (FIG. 6F), argon (FIG. 6G), germanium (FIG. 6H), and indium (FIG. 6I). FIG. 6J is an SEM image of an ALD silicon nitride deposition map of a comparison wafer that has not undergone step S203 in FIG. 2.

Due to the design of the method for manufacturing a semiconductor memory device according to the present disclosure, the second silicon nitride layer can be grown at an increased rate. A silicon nitride layer (i.e., the second silicon nitride layer) having good quality with a seam having a short length is achieved in accordance with the method of the present disclosure. Such method avoids a problem encountered in the prior art wherein a seam having a greater length contacts an edge of a contact plug of a semiconductor memory device. Hence, a leakage problem at subsequent operations of semiconductor manufacture can be avoided, and the product yield can be significantly improved.

It should be understood that the preceding examples are included to demonstrate specific embodiments of the present disclosure. It should be appreciated by those of skill in the art that the techniques disclosed in the examples which follow represent techniques discovered by the inventors to function well in the practice of the present disclosure, and thus can be considered to constitute preferred modes for its practice. However, it should also be understood that the present disclosure is not intended to be limited to the particular forms disclosed. Rather, the different aspects of the disclosed process may be utilized in various combinations and/or independently. Thus, the present disclosure is not limited to only those combinations shown herein, but rather may include other combinations. Further, those of skill in the art should, in light of the present disclosure, appreciate that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A method for manufacturing a semiconductor memory device, comprising the steps of:
providing a semiconductor memory substrate including a plurality of trenches;
conformally forming a first silicon nitride layer on the plurality of trenches;
performing ion implantation using atomic layer deposition (ALD) to implant a dopant at a tilting angle (θ) of between about 5 degrees and about 30 degrees to form a dopant-implanted layer on the first silicon nitride layer; and
growing a second silicon nitride layer on the dopant-implanted layer.

2. The method according to claim 1, wherein the semiconductor memory substrate is selected from the group consisting of a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a group III-V compound semiconductor, and combinations thereof.

3. The method according to claim 1, wherein the trench has an aspect ratio of between 10:1 and 60:1.

4. The method according to claim 1, wherein the step of conformally forming a first silicon nitride layer on the plurality of trenches is carried out using atomic layer deposition (ALD), atomic layer epitaxy (ALE), atomic layer chemical vapor deposition (ALCVD), spin-coating, sputtering, chemical vapor deposition (CVD), or physical vapor deposition (PVD).

5. The method according to claim 1, wherein the step of performing ion implantation is carried out using ALD to implant a dopant at a tilting angle (θ) of between about 5 degrees and about 20 degrees.

6. The method according to claim 1, wherein the step of performing ion implantation is carried out using ALD to implant a dopant at a tilting angle (θ) of about 7 degrees.

7. The method according to claim 1, wherein the step of performing ion implantation is carried out using ALD to implant a dopant at a tilting angle (θ) of about 17 degrees.

8. The method according to claim 1, wherein the step of performing ion implantation is carried out using a dopant selected from the group consisting of fluorine, carbon, boron, arsenic, phosphorus, nitrogen, argon, germanium, and indium.

9. The method according to claim 1, wherein the step of performing ion implantation is carried out with an ion dose in a range of about 3.0×10¹³ to about 5.0×10¹⁵ ions/cm².

10. The method according to claim 1, wherein the step of performing ion implantation is carried out with an energy in a range of about 100 eV to about 100 KeV.

11. A method for manufacturing a semiconductor memory device, comprising the steps of:
providing a semiconductor memory substrate including a plurality of trenches, wherein each trench has a bottom and a pair of sidewalls;
conformally depositing a first silicon nitride layer on the plurality of trenches;
performing ion implantation to form a dopant-implanted layer on the first silicon nitride layer, wherein the bottom of the trench receives a first ion dose and the pair of sidewalls of the trench receive a second ion dose, and the first ion dose is 10 to 100 times the second ion dose; and
growing a second silicon nitride layer on the dopant-implanted layer.

12. The method according to claim 11, wherein the semiconductor memory substrate is selected from the group consisting of a silicon (Si) substrate, a germanium (Ge) substrate, a silicon germanium (SiGe) substrate, a silicon-on-sapphire (SOS) substrate, a silicon-on-quartz substrate, a silicon-on-insulator (SOI) substrate, a group III-V compound semiconductor, and combinations thereof.

13. The method according to claim 11, wherein the trenches have an aspect ratio of between 10:1 and 60:1.

14. The method according to claim 11, wherein the step of conformally forming a first silicon nitride layer on the plurality of trenches is carried out using spin-coating, sputtering, chemical vapor deposition (CVD), or physical vapor deposition (PVD).

15. The method according to claim 11, wherein the step of performing ion implantation is carried out using a dopant selected from the group consisting of fluorine, carbon, boron, arsenic, phosphorus, nitrogen, argon, germanium, and indium.

16. The method according to claim 11, wherein the first ion dose is in a range of about 3.0×10¹⁴ ions/cm² to about 5.0×10¹⁵ ions/cm².

17. The method according to claim 11, wherein the first ion dose is in a range of about 3.0×10¹⁴ ions/cm² to about 5.0×10¹⁵ ions/cm², and the first ion dose is 50 times the second ion dose.

18. The method according to claim 11, wherein the first ion dose is in a range of about 3.0×10¹⁴ ions/cm² to about 5.0×10¹⁵ ions/cm², and the first ion dose is 70 times the second ion dose.

19. The method according to claim 11, wherein the step of performing ion implantation is carried out with an energy in a range of about 100 eV to about 100 KeV.

20. The method according to claim 11, wherein the step of performing ion implantation is carried out with an energy in a range of about 1 KeV to about 100 KeV.
